(19) United States
(12) Patent Application Publication
(10) Pub. No.: US 2015/0124313 A1
(43) Pub. Date: May 7, 2015

(54) OPTICAL COMMUNICATION APPARATUS AND CONTROL METHOD OF OPTICAL COMMUNICATION APPARATUS

(71) Applicant: Fujitsu Optical Components Limited, Kawasaki-shi (JP)

(72) Inventor: Kensuke Takahashi, Kawasaki (JP)

(73) Assignee: Fujitsu Optical Components Limited, Kawasaki (JP)

(21) Appl. No.: 14/484,741

(22) Filed: Sep. 12, 2014

(30) Foreign Application Priority Data
Nov. 5, 2013 (JP) 2013-229568

(51) Int. Cl. H01S 3/16; H01S 5/04

(52) U.S. Cl. CPC H01S 3/1603; H01S 5/04
USPC 359/337; 359/344; 359/341.5

(57) ABSTRACT

Provided are an optical amplifier, a light reception element, and a controller configured to decrease a gain of the optical amplifier according to an optical signal power input to the optical amplifier in response to a detection of a recovery of the optical signal input to the optical amplifier from an interruption of the optical signal and to increase the gain of the optical amplifier so that an input optical power to the light reception element approaches a target value after the decreasing of the gain.

### CROSS-REFERENCE TO RELATED APPLICATION

This application is based upon and claims the benefit of priority of the prior Japanese Patent Application No. 2013-229568, filed on Nov. 5, 2013, the entire contents of which are incorporated herein by reference.

### FIELD

The embodiments discussed herein are related to an optical communication apparatus and a control method of the optical communication apparatus.

### BACKGROUND

In recent years, with an explosive increase in demand for the Internet, an experiment with an upgrade of the speed of the Internet has been made in an access network such as a fiber to the home (FTTH) or in a backbone network. For one of next generation networks, an optical transceiver used in a gigabit Ethernet such as a 40-Gbit base Ethernet and a 100-Gbit base Ethernet is actively developed. The “Ethernet” is a registered trademark. In the course of development, in order to improve a dynamic range of an optical transceiver, an optical receiver equipped with a variable optical attenuator (VOA) and a semiconductor amplifier (SOA) is under study.

Further, there is a demand for a 100-Gbps base optical transceiver compliant to the specification of CFP (100G Form-factor Pluggable) to compress a time taken from a light extinction to a light emission, in order to compress a time taken for establishing a signal communication. For this reason, there is a demand for the optical receiver to improve a response speed thereof. Therefore, for a 100-Gbps base optical receiver having an optical amplifier such as the SOA, the optical amplifier is desired to improve a response speed thereof.

In the optical receiver equipped with the optical amplifier, for example, a light reception element and an optical component such as a photo diode (PD) is possibly damaged due to an optical transient response (such as an optical overshoot and an optical surge) at a time when an input optical power changes rapidly (for example, when the input optical power is rapidly increased from an optical interruption state). In order to prevent the damage, a technology disclosed in JP 08-331062 A controls a gain of an optical amplifier to be decreased according to an input optical power. According to the gain control, it is possible to suppress the optical surge and the like to prevent a light reception element and the like from being damaged.

Other technologies pertaining to a gain control of an optical amplifier are disclosed in JP 2004-179233 A and JP 2010-186919 A, for example. JP 2004-179233 A and JP 2010-186919 A disclose that the gain of the SOA is feed-forward-controlled to address an optical bust signal. Further, JP 2004-120669 A and JP 2010-45606 A discloses that an output characteristic of an SOA is stabilized by a variable control of an optical level input to the semiconductor amplifier.

According to the gain control disclosed in JP 08-331062 A, it is possible to prevent the damage of the light reception element and the like caused by the optical surge. However, JP 08-331062 A merely discloses that the gain of the amplifier is controlled to be decreased at the time when the input optical power changes rapidly, and an optical response speed (for example, a rising time) at that time becomes delayed. For this reason, a delay is occurred in a time taken for establishing a signal communication.

FIG. 16 illustrates an example of a response characteristic of an input optical power to the light reception element at the time when the input optical power changes rapidly. The characteristic denoted by the solid line 300 illustrates a characteristic in a case where the gain of the optical amplifier is controlled to be decreased according to the optical input power as disclosed in JP 08-331062 A. The rising time of the optical transient response is delayed by decreasing the gain of the optical amplifier at the rapid optical power change. Thereby, it is possible to prevent the light reception element from being damaged.

In contrast, the characteristic denoted by the solid line 100 illustrates a characteristic in a case where the above gain decreasing of the optical amplifier is not performed. As can be seen from the comparison between the characteristics 100 and 300, when the gain of the optical amplifier is decreased in response to the rapid optical power change, a delay is occurred until the optical input power to the light reception element becomes stabilized at a target value near a rated power, for example. The delay causes a delay in a time taken for establishing the signal communication. Meanwhile, all of the patent documents of JP 2004-179233 A, JP 2010-186919 A, JP 2004-120669 A and JP 2010-45606 A fails to disclose or suggest any countermeasures for the rapid optical power change as mentioned above.

### SUMMARY

An aspect of an optical communication apparatus includes an optical amplifier configured to amplify a received optical signal, a light reception element configured to receive the optical signal amplified by the optical amplifier, and a controller. The controller is configured to decrease a gain of the optical amplifier according to an optical signal power input to the optical amplifier in response to a detection of a recovery of the optical signal input to the optical amplifier from an interruption of the optical signal, and to increase the gain of the optical amplifier so that an input optical power to the light reception element approaches a target value after the decreasing of the gain.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a block diagram illustrating an exemplary configuration of an optical receiver according to a first embodiment;

FIG. 2 is a flowchart for describing an exemplary operation of the optical receiver illustrated in FIG. 1;

FIG. 3 is a graph illustrating an example of a temporal variation (response characteristic) of input optical power to a light reception element at the rapid optical power change;

FIG. 4 is a block diagram illustrating an exemplary configuration of the optical receiver, focusing on a gain subtraction circuit and a gain addition circuit illustrated in FIG. 1;

FIG. 5 is a diagram illustrating an example of a time response pertaining to a LOS cancellation at the rapid optical power change;

FIG. 6 is a block diagram illustrating an exemplary configuration of an optical receiver according to a second embodiment;

FIG. 7 is a diagram illustrating an exemplary configuration of a LOS cancellation delay prevention circuit illustrated in FIG. 6;

FIG. 8 is a timing chart for describing an exemplary operation of the LOS cancellation delay prevention circuit illustrated in FIG. 7;

FIG. 9 is a block diagram illustrating an exemplary configuration of an optical repeater according to a third embodiment;

FIG. 10 is a block diagram illustrating an exemplary configuration of the optical repeater, focusing on the gain subtraction circuit and the gain addition circuit illustrated in FIG. 9;

FIGS. 11 to 13 are block diagrams illustrating variations of a signal level detector illustrated in FIG. 9;

FIG. 14 is a block diagram illustrating an exemplary configuration of an optical receiver according to a modified example of the first embodiment;

FIG. 15 is a graph illustrating an example of a temporal variation (response characteristic) of an input optical power when an accelerating rate of the input optical power to a light reception element is varied by a response variable circuit illustrated in FIG. 14; and

FIG. 16 is a graph illustrating an example of a temporal variation of an input optical power to a light reception element in the related art at the rapid optical power change.

### DESCRIPTION OF EMBODIMENTS

Hereinafter, embodiments of the invention will be described with reference to the drawings. However, the following embodiments are given as merely exemplary, and it is not intended to exclude various modifications and various technical applications which are not specified in the embodiments. In addition, portions denoted with the same symbols in the drawings used in the following embodiments represent the same or similar portions if not otherwise specified.

### First Embodiment

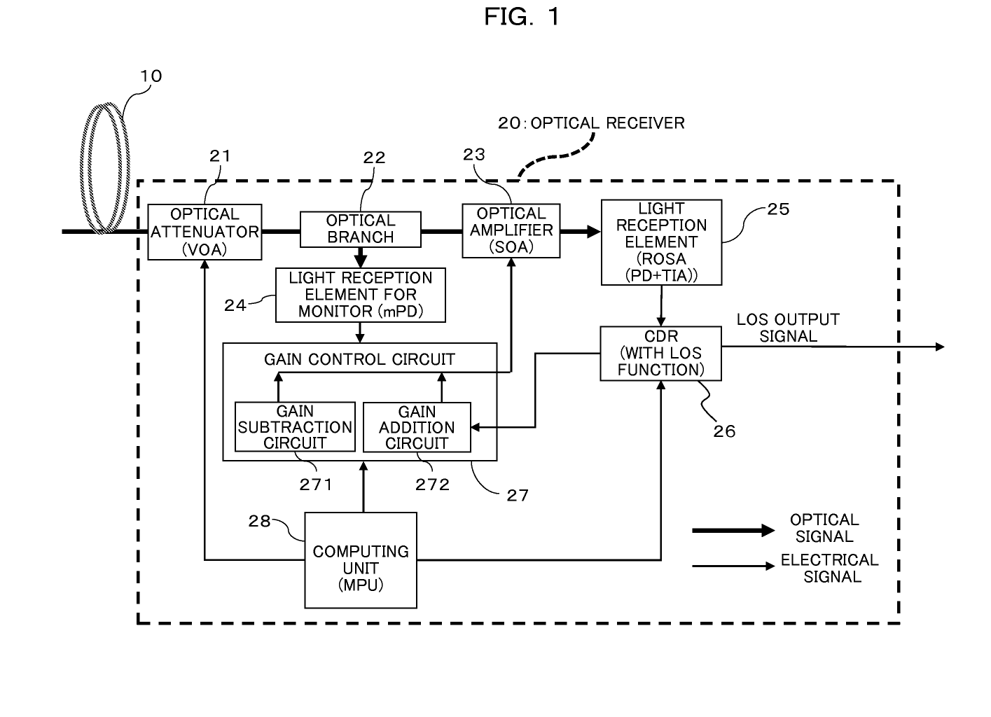

FIG. 1 is a block diagram illustrating an exemplary configuration of an optical receiver according to a first embodiment. An optical receiver 20 illustrated in FIG. 1, for example, receives an optical signal transmitted through an optical transmission line 10. The optical signal to be transmitted through the optical transmission line 10 may be an optical signal with one wavelength, or may be a WDM optical signal in which optical signals with multiple wavelengths are multiplexed. The optical receiver 20 is, for example, applicable to a reception system of a 100-Gbps base optical transceiver.

The optical receiver 20 includes, for example, a variable optical attenuator (VOA) 21, an optical branch 22, an optical amplifier 23, a monitor light reception element 24, a light reception element 25, a CDR (with LOS function) unit 26, a gain control circuit 27, and an MPU 28 as an example of a computing unit.

The VOA 21 is controlled its attenuation amount (or loss) by the computing unit 28 to adjust the output optical power of the optical signal received from the optical transmission line 10 to the optical branch section 22.

The optical branch 22 branches the output light of the VOA 21 to output one of the branched lights as a monitor light to the monitor light reception element 24 and to output the other of the branched lights to the optical amplifier 23. An optical coupler is applicable to the optical branch 22, for example.

The optical amplifier 23 amplifies the light input from the optical branch 22 and outputs the amplified light to the light reception element 25. The optical amplifier 23 is, for example, a semiconductor amplifier (SOA), and an amplification gain thereof is controlled by the gain control circuit 27. The gain of the SOA 23 is set to an initial setting value at an optical interruption state. The initial setting value is, for example, a value which satisfies a minimum reception level of the light reception element 25. A detailed example of gain control by the gain control circuit 27 will be described later.

The monitor light reception element 24 outputs an electrical signal according to a light reception power of the monitor light branched at the optical branch 22 to the gain control circuit 27. A photo diode (PD) is applicable to the monitor light reception element 24, for example. The “mPD” illustrated in FIG. 1 represents an abbreviation of a “monitor PD”. The monitor PD 24 is an example of a detector which detects the input optical signal power.

The light reception element 25 receives the output light of the optical amplifier 23, and outputs an electrical signal (for example, a voltage) according to the light reception power to the CDR (with LOS function) unit 26. A receiver optical subassembly (ROSA) which includes a PD and a transimpedance amplifier (TIA) is applicable to the light reception element 25, for example. Hereinafter, the light reception element 25 may be denoted as the ROSA 25.

The CDR (with LOS function) unit 26 restores a clock signal and a data signal from the electrical signal output from the ROSA 25. The CDR is an abbreviation of “clock and data recovery”. When the amplitude of the output voltage of the ROSA 25 is less than a lower limit of a predetermined reception range, a minimum reception sensitivity of the ROSA 25 is not satisfied, and therefore, the CDR (with LOS function) unit 26 outputs an alarm signal indicating a loss of an optical signal. A LOS (Loss of Signal) alarm is an example of the alarm signal. Therefore, the above-mentioned lower limit may be referred to as a “LOS issuance level”.

The LOS alarm may be cancelled when the amplitude of the output voltage of the ROSA 25 becomes equal to or larger than the LOS issuance level, but the LOS alarm may be frequently and repeatedly issued and cancelled at a level where the amplitude of the output voltage of the ROSA 25 is easily influenced by noises. Therefore, a LOS cancellation level may be set to a level larger than the LOS issuance level (while less than a maximum output level of the ROSA 25). The LOS alarm is cancelled (the output stops) when the amplitude of the output voltage becomes equal to or larger than the LOS cancellation level.

The LOS alarm may be referred to as a “CDR LOS signal”. The CDR LOS signal indicates, for example, a LOS alarm issuance when the signal is at an H level, and indicates a LOS alarm cancellation when the signal is at an L level. The CDR LOS signal is provided to a gain addition circuit 272 (to be described later) of the gain control circuit 27.

The MPU 28 performs control on the attenuation amount of the VOA 21 (hereinafter, it may be referred to as the “VOA loss”), setting on the CDR (with LOS function) unit 26 such as the LOS issuance level and the LOS cancellation level, and setting on the gain control circuit 27. For example, the setting on the gain control circuit 27 may include a setting of a target value and an upper limit of the gain of the SOA 23.

When a small level signal equal to or smaller than the LOS cancellation level is input, the MPU 28 controls (or sets) the VOA 21 to minimize the VOA loss in order to satisfy the minimum reception level, for example. In contrast, when a large level signal equal to or larger than the LOS cancellation level is input, the MPU 28 controls the VOA 21 to increase the VOA loss in order to prevent the ROSA 25 from being damaged due to an optical signal with a level exceeding a maximum reception level being input to the ROSA 25. The MPU 28 may control the gain of the SOA 23 not to cause an error in the clock and data recovery of the CDR (with LOS function) unit 26 when the small level signal is input.

Through these controls, the optical receiver 20 can satisfy a predetermined reception characteristic in a wide dynamic range from the minimum reception level to the maximum reception level. However, the optical receiver 20 is on standby while minimizing the VOA loss in order to satisfy the minimum reception level in a no-signal state (the optical interruption state). The VOA 21 and the SOA 23 are too slow in response to the control of the MPU 28 at a time when the input optical power of light rapidly increases from the no-signal state (the optical interruption state) where light is not input to the optical receiver 20. For this reason, an optical overshoot, an optical surge, or the like may occur to cause the ROSA 25 to receive a signal with a power level exceeding the maximum reception level. In this case, a current exceeding a rated current value may flow in the ROSA 25, thereby possibly causing a damage to the ROSA 25.

According to the aforementioned gain control disclosed in JP 08-331062 A, it is possible to prevent the light reception element from being input a signal (such as optical surge) with a power level exceeding the maximum reception level at the rapid optical power change. However, the gain control is simply to reduce an amplifier gain, and the delay in optical response (for example, a rising time) is occurred. Therefore, at the rapid optical power change, the delay is occurred in a time until the optical receiver 20 becomes operable. As a result, a delay is occurred in a time taken for establishing a signal communication, a LOS alarm cancellation time, a response time of a reception power module, and the like. The “LOS alarm cancellation time” means a time until the LOS alarm is cancelled after the LOS alarm is issued.

Herein, in the embodiment, an increase in a speed of the optical response (the rising time) is achieved using the gain control circuit 27 while preventing the ROSA 25 from being input a signal (such as an optical surge) with a power level exceeding the maximum reception level at the rapid optical power change. As an example of a factor causing the rapid optical power change, there are (1) an optical shutdown cancellation of an optical transmitter (from light-off to light-on), (2) optical line abnormality, and (3) wiggles.

The gain control circuit 27 of the embodiment controls the gain of the SOA 23 based on the output (for example, a current value) of the monitor PD 24, a monitor value (for example, a current value) of a gain control signal which is given to the SOA 23, and the CDR LOS signal of the CDR (with LOS function) unit 26. The input optical power to the ROSA 25 is controlled by the gain control. Therefore, the gain control circuit 27 may be referred to as a “light reception element (or ROSA) input power control circuit 27”. The gain control circuit 27 and the MPU 28 may together be referred to as a “controller” or a “control block”.

Herein, an example of the gain control of the SOA 23 includes a decrease control to decrease the gain of the SOA 23 and an increase control of the gain of the SOA 23 during a period from the rapid optical power change is occurred until the input optical power to the ROSA 25 reaches a target level which is smaller than the maximum reception level.

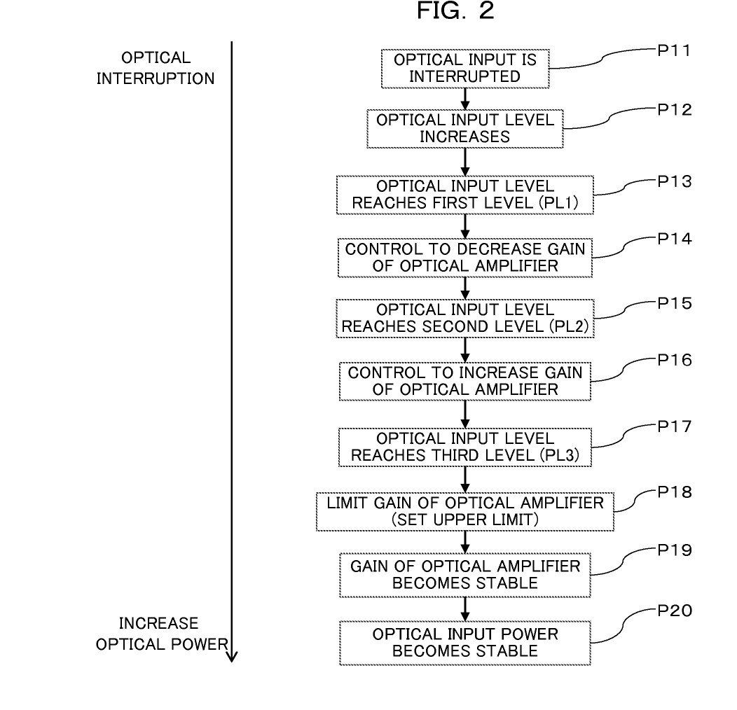

For example, when a current value according to the light reception power in the monitor PD 24 reaches a first level PL1 in response to the rapid optical power change, the gain control circuit 27 performs the decrease control of the gain of the SOA 23 (processes P11 to P14 of FIG. 2). As a non-limited example, the first level PL1 is set to a level which is larger than the LOS issuance level and smaller than the LOS cancellation level. Until the amplitude of the output voltage of the ROSA 25 reaches the LOS cancellation level, a LOS alarm is issued by the CDR (with LOS function) unit 26.

Thereafter, when the light reception power of the monitor PD 24 reaches a second level PL2 (for example, the LOS cancellation level) larger than the first level PL1, the gain control circuit 27 performs the increase control of the gain of the SOA 23 (processes P15 and P16 of FIG. 2). For example, the gain control circuit 27 performs a feedback control on the gain of the SOA 23 such that a monitor value of a current value which is an example of the gain control signal given to the SOA 23 approaches a target value. The target value is, for example, set to a value equal to or smaller than the rated current value of the ROSA 25. The rising time of the optical response is compressed by the above feedback control. When the amplitude of the output voltage of the ROSA 25 reaches the LOS cancellation level, the CDR (with LOS function) unit 26 stops (or cancels) the issuance of the LOS alarm.

Subsequently, when the amplitude of the output voltage of the ROSA 25 reaches a third level PL3 larger than the second level, the gain control circuit 27 sets the gain of the SOA 23 to a predetermined upper limit value so as to limit or stop the increase control of the gain (process P18 of FIG. 2). At this time, the gain of the SOA 23 may be controlled to be decreased. The third level PL3 is, for example, set to a value (target value) in a range larger than the LOS cancellation level and not exceeding the rated input power to the ROSA 25. Therefore, the gain of the SOA 23 becomes stable, and then the optical input power becomes stable and the rapid optical power change stops (processes P19 and P20 of FIG. 2).

In order to achieve the above gain control of the SOA 23, the gain control circuit 27 includes, for example, a gain subtraction circuit 271 and the gain addition circuit 272 as illustrated in FIG. 1.

When the input optical power to the optical receiver 20 reaches the first level PL1, the gain subtraction circuit 271 performs a subtract operation on the gain of the SOA 23 to be decreased according to the input optical power based on current information from the monitor PD 24. Therefore, the first level PL1 may be referred to as a “gain subtraction start level”. The “gain subtraction start level” is, for example, set by the MPU 28.

When the input optical power reaches the second level PL2 (for example, the LOS cancellation level) in response to the rapid optical power change, the gain addition circuit 272 performs an add operation on the gain of the SOA 23 by the above-mentioned feedback control. Therefore, the second level PL2 may be referred to as a “gain addition start level”. Further, when the input optical power reaches the third level PL3 near the target value for example and the monitor value of the current value which is an example of the gain control signal given to the SOA 23 reaches the target value, the gain addition circuit 272 limits or stops the increase of the gain of the SOA 23 (or may decrease the gain of the SOA 25). The gain addition start level, a gain addition amount, and the target value of the gain addition circuit 272 may be set by the MPU 28, for example.

By using the gain subtraction circuit 271 and the gain addition circuit 272, it is possible to prevent the ROSA 25 from being input an optical power exceeding the maximum reception level due to an optical transient response at the rapid optical power change and from being damaged. Also, a time taken until the optical receiver 20 becomes operable can be shortened by stabilizing the gain of the SOA 23. Therefore, it is possible to suppress a delay in a time taken for establishing the signal communication, a time taken until the LOS alarm is cancelled, and a response time of the reception power monitor.

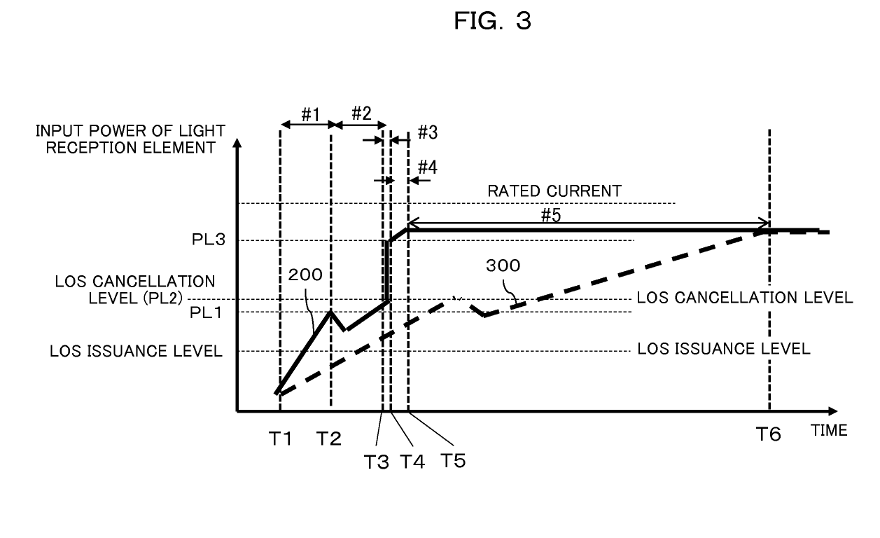

Next, the above-mentioned gain control using the gain control circuit 27 (the gain subtraction circuit 271 and the gain addition circuit 272) will be described with reference to FIG. 3. FIG. 3 is a graph illustrating an example of a temporal variation (response characteristic) of input optical power to the ROSA 25 at the rapid optical power change.

In FIG. 3, a characteristic denoted by the solid line 200 illustrates an example of a temporal variation of the input optical power to the ROSA 25 in a case where the gain control is performed by the gain control circuit 27 of the embodiment. A characteristic denoted by the dotted line 300 illustrates a temporal variation of the input optical power to the ROSA 25 in a case (a case of no gain addition) where the aforementioned gain control according to JP 08-331062 A is performed.

As illustrated in FIG. 3 (the solid line 200), the input optical power to the ROSA 25 is increased in response to the rapid optical power change occurred at Time T1, and the input optical power reaches the first level PL1 at Time T2. Both of the gain addition circuit 272 and the gain subtraction circuit 271 are in the OFF state (or non-operation state) during a period between Times T1 and T2.

When the input optical power reaches the first level PL1 at Time T2, the gain subtraction circuit 271 becomes the ON state to start the subtract operation to decrease the gain of the SOA 23 according to an output current value of the monitor PD 24. At this time, the gain addition circuit 272 remains in the OFF state. Therefore, the gain of the SOA 23 is decreased, and thus it is possible to suppress the optical overshoot caused by the rapid optical power change. Accordingly, it is possible to suppress the ROSA 25 from being damaged due to the optical surge.

Thereafter, the input optical power to the ROSA 25 is increased as the input optical power to the optical receiver 20 is increased. When the input optical power to the ROSA 25 reaches the LOS cancellation level (an example of the second level PL2) at Time T3, the gain addition circuit 272 becomes the ON state to start the add operation on the gain of the SOA 23 according to the amplitude of the output voltage of the ROSA 25. At this time, the gain subtraction circuit 271 remains in the ON state. With starting the operation of the gain addition circuit 272, the optical rising speed is accelerated, and the optical response is accelerated. As a result, a time taken until the optical receiver 20 becomes operable is shortened at the rapid optical power change, and a time taken for establishing the signal communication is shortened.

Subsequently, when the input optical power to the ROSA 25 reaches the third level PL3 near the target value at Time T4, the gain addition circuit 272 becomes the OFF state, and the gain increased by the gain addition circuit 272 reaches the upper limit value. At this time, the gain subtraction circuit 271 remains in the ON state. When the gain addition circuit 272 enters the OFF state, the optical rising speed is reduced. Therefore, it is possible to prevent the ROSA 25 from being damaged due to the optical surge. Thereafter, the gain of the SOA 23 becomes stable by Time T5, and the optical input power to the ROSA 25 becomes stable on and after Time T5 and the rapid optical power change stops.

The ON and OFF states of the gain subtraction circuit 271 and the gain addition circuit 272 are listed in the following Table 1 during Period #1 between Times T1 and T2, Period #2 between Times T2 and T3, Period #3 between Times T3 and T4, and Period #4 between Times T4 and T5.

TABLE 1

| | Gain subtraction | Gain addition |
|---|---|---|
| Period | circuit | circuit |
| #1(T1-T2) | OFF | OFF |
| #2(T2-T3) | ON | OFF |
| #3(T3-T4) | ON | ON |
| #4(T4-T5) | ON | OFF |

Herein, as can be seen from the comparison between characteristics 200 and 300 illustrated in FIG. 3, since the input optical power to the ROSA 25 becomes stable at Time T6 in the gain control according to JP 08-331062 A, a delay is occurred by a time difference #5 between Times T5 and T6 until the input optical power is stabilized. In other words, according to the gain control of the embodiment, it is possible to shorten a time by the time difference #5 until the input optical power to the ROSA 25 is stabilized.

As described above, according to the first embodiment, by using the gain control circuit 27 (the gain subtraction circuit 271 and the gain addition circuit 272), it is possible to increase an optical response speed of the optical receiver 20 while suppressing the optical transient response (the optical surge) at the rapid optical power change. Therefore, it is possible to suppress a delay in a time taken for establishing the signal communication time, the LOS alarm cancellation time, and the response time of the reception power monitor. As a result, it is possible to shorten a time until the optical receiver 20 becomes operable. Therefore, for example, even in a case where a decrease in time (for example, 2 msec or less) taken from a light extinction to a light emission in a 100-Gbps base optical transmitter (CFP) is realized, it is possible to realize the 100-Gbps base optical receiver 20 which is sufficiently compatible with the decrease of the light extinction-emission time.

### Detailed Exemplary Configuration of Gain Subtraction Circuit 271 and Gain Addition Circuit 272

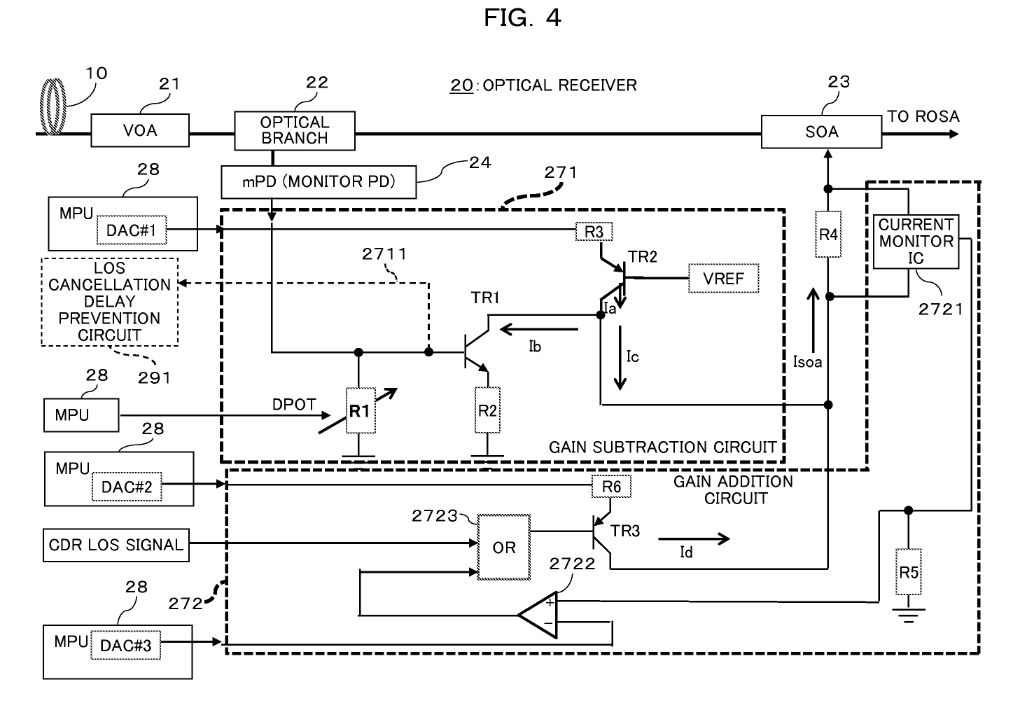

Next, FIG. 4 illustrates an exemplary configuration focusing on the gain subtraction circuit 271 and the gain addition circuit 272 described above.

### Gain Subtraction Circuit 271

As illustrated in FIG. 4, the gain subtraction circuit 271 includes, for example, transistors TR1 and TR2, a digital variable resistor R1, and resistors R2 and R3. As a non-limited example, the transistors TR1 and TR2 are bipolar transistors. However, other types of transistors such as a field effect transistor (FET) are applicable to the transistors TR1 and TR 2.

The base of the transistor TR1 is connected to the output of the monitor PD 24. Further, the digital variable resistor (DPOT) R1 is connected to the base of the transistor TR1 in parallel. The resistance value of the digital variable resistor R1 is controlled by the MPU 28, for example.

A voltage level to turn on the transistor TR1 is adjusted by controlling the resistance value of the digital variable resistor R1. The collector of the transistor TR1 is connected to the collector of the transistor TR2, and the emitter of the transistor TR1 is earthed through the resistor R2.

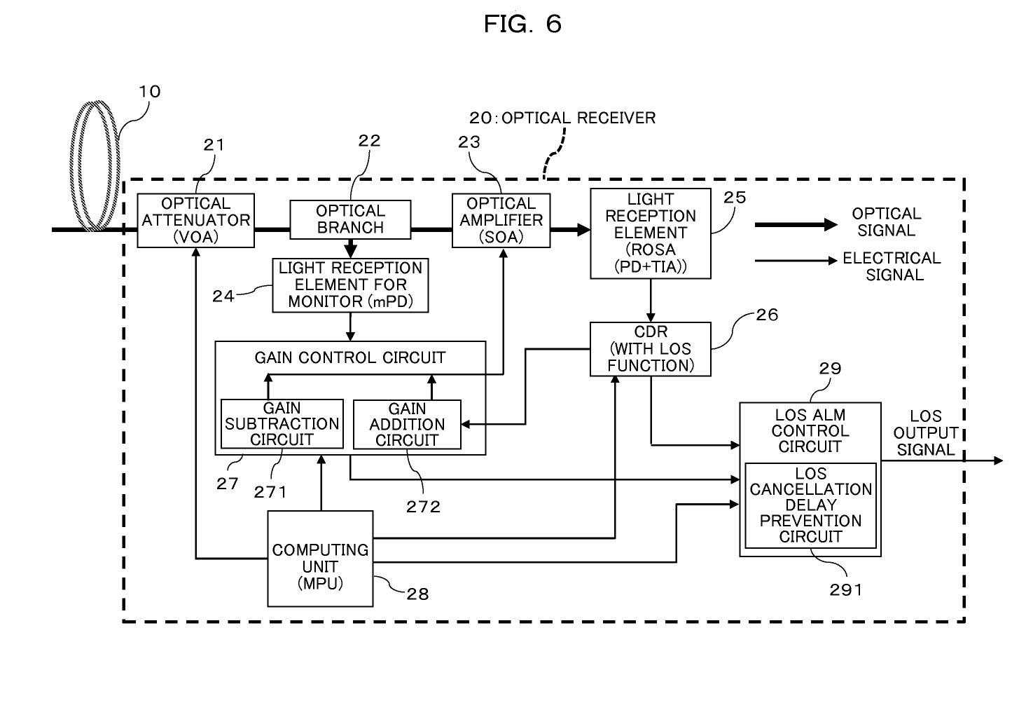

In FIG. 4, the signal line denoted by a solid arrow 2711 illustrates that in a case where a LOS cancellation delay prevention circuit 291 (see FIG. 6) described later in a second embodiment is provided in the optical receiver 20, the base of the transistor TR1 is connected to the LOS cancellation delay prevention circuit 291. In other words, this means that optical signal level information monitored by the monitor PD 24 is input to the LOS cancellation delay prevention circuit 291.

A reference voltage (VREF) is applied to the base of the transistor TR2. The emitter of the transistor TR2 is connected to the MPU 28 (for example, a digital to analog converter (DAC #1)) through the resistor R3. Further, the collector of the transistor TR2 is connected to the SOA 23 through a resistor R4.

A current Ia flowing in the collector of the transistor TR2 is adjusted by the MPU 28 (DAC #1) which controls an emitter voltage of the transistor TR2. When the transistor TR1 is turned on, a part of the current Ia flows to the collector of the transistor TR1 as a current Ib. Therefore, a current Ic output from the collector of the transistor TR2 to the SOA 23 is expressed as Ic=Ia−Ib.

Hereinafter, the operation of the gain subtraction circuit 271 with the above-mentioned configuration will be described.

Firstly, the gain of the SOA 23 is determined by DAC #1 of the MPU 28. The determination is performed in the no-signal state. In the no-signal state, the transistor TR1 is in the OFF state, and the gain of the SOA 23 is determined by the transistor TR2. Subsequently, an attenuation start level is determined by using the MPU 28 and the digital variable resistor R1. In this case, the determination is made in consideration of the reception sensitivity of the ROSA 25.

When an optical signal is input to the optical receiver 20, a base voltage of the transistor TR1 is increased according to the output of the monitor PD 24, and the transistor TR1 is turned on at a certain level. The turning-on level of the transistor TR1 is determined by the digital variable resistor R1. When the transistor TR1 is turned on, the current Ib flows from the collector of the transistor TR2 to the collector of the transistor TR1.

When an input optical signal level to the optical receiver 20 (in other words, the output level of the monitor PD 24) is increased, the current Ib is increased. Therefore, the current Ic expressed by Ic=Ia−Ib is decreased when the input optical signal level is increased. In this way, the gain subtraction circuit 271 operates to decrease the gain of the SOA 23 at the rapid optical power change by way of controlling the current Ic.

### Gain Addition Circuit 272

Meanwhile, as illustrated in FIG. 4, the gain addition circuit 272 includes a current monitor IC 2721, a comparator 2722, a logical OR circuit 2723, a transistor TR3, and resistors R5 and R6. As a non-limited example, the transistor TR3 is a bipolar transistor, but other types of transistors such as a FET is applicable to the transistor TR3.

The current monitor IC 2721 is an example of a current detection circuit, and detects (or monitors) a current Isoa flowing to the SOA 23 based on a voltage between the both ends of the resistor R4. The output of the current monitor IC 2721 is connected to one input terminal (the non-inverting input (+)) of the comparator 2722. The ground resistor R5 is connected to the output line in parallel from the current monitor IC 2721 to the comparator 2722. The other input terminal (the inverting input (−)) of the comparator 2722 is connected to the MPU 28 (for example, DAC #3).

The output of the comparator 2722 is connected to one input terminal of the OR circuit 2723. The output (LOS signal) of the CDR (with LOS function) unit 26 is input to the other input terminal of the OR circuit 2723.

The output of the OR circuit 2723 is connected to the base of the transistor TR3. The emitter of the transistor TR3 is connected to the MPU 28 (for example, DAC #2) through the resistor R6. The collector of the transistor TR3 is connected to a signal line which is input to the SOA 23 from the collector of the transistor TR2 of the gain subtraction circuit 271 through the resistor R4.

Hereinafter, the operation of the above-mentioned gain addition circuit 272 will be described.

Firstly, the gain addition amount of the SOA 23 is determined by DAC #2 of the MPU 28. When the transistor TR3 enters the ON state, a current Id is output from the collector of the transistor TR3. The current Id is added to the current Ic which is output from the collector of the transistor TR2 of the gain subtraction circuit 271. Therefore, since the current Isoa given to the SOA 23 is increased, the gain of the SOA 23 is increased and the optical transient response of the SOA 23 is accelerated.

The turning ON/OFF timing of the transistor TR3 is determined based on the CDR LOS signal and the upper limit value of the current Isoa. For example, after the amplitude of the output voltage of the ROSA 25 exceeds the LOS cancellation level, the CDR LOS signal input to the one input terminal of the OR circuit 2723 falls in the L level. Meanwhile, the output of the comparator 2722 which is input to the other input terminal of the OR circuit 2723 is at the L level until the current value of the current Isoa detected by the current monitor IC 2721 reaches the target value which is set from the MPU 28 (DAC #3).

Therefore, the output of the OR circuit 2723 falls in the L level, and the transistor TR3 is turned ON state. Therefore, the current Id is output from the collector of the transistor TR3 to thereby increase the current Isoa.

Thereafter, when the current value of the current Isoa detected by the current monitor IC 2721 exceeds the target value set from the MPU 28 (DAC #3), the output of the comparator 2722 rises to the H level. Therefore, the output of the OR circuit 2723 rises to the H level, and the transistor TR3 is turned OFF state. The target value of the current Isoa is adjusted by the MPU 28 (DAC #3) not to exceed the rated input level of the ROSA 25. Therefore, the optical rising time is delayed, and thus it is possible to prevent the ROSA 25 from being input the optical surge by the addition of the gain of the SOA 23.

As described above, the gain addition circuit 272 operates such that the gain of the SOA 23 is increased at the rapid optical power change by controlling the turning ON/OFF of the transistor TR3.

### Second Embodiment

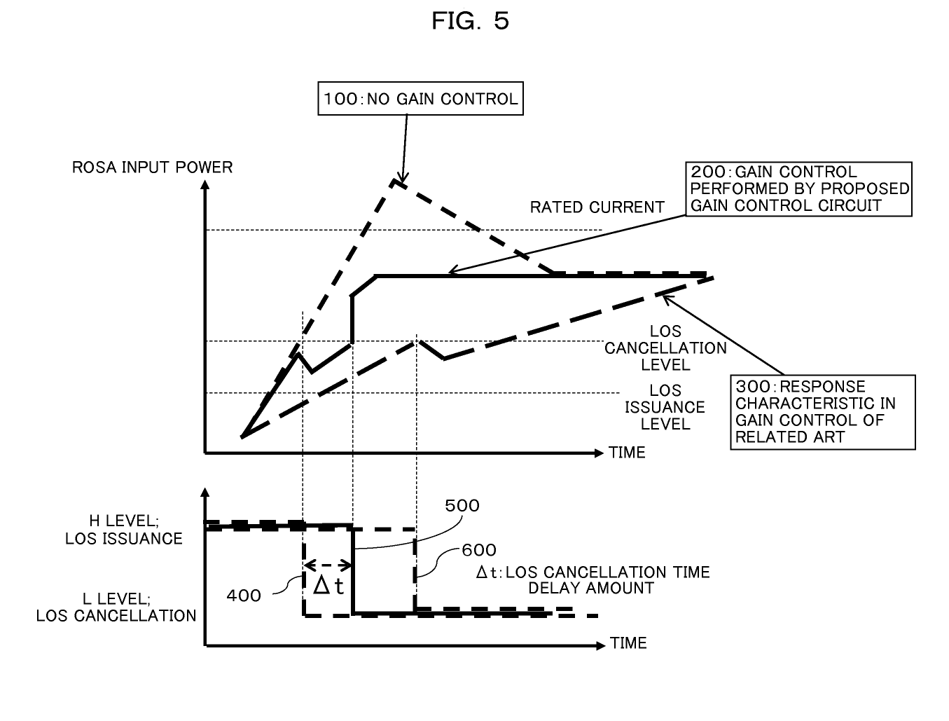

FIG. 5 is a diagram illustrating an example of a time response pertaining to a LOS cancellation at the rapid optical power change in which the input optical power to the optical receiver 20 is rapidly increased from the no-signal state (or the optical interruption state). Similarly to FIG. 3, the upper portion of FIG. 5 illustrates a temporal variation (characteristics) of the input optical power to the ROSA 25.

In the upper portion of FIG. 5, the solid line 100 indicates a characteristic in a case where the gain control of the SOA 23 is not performed at the rapid optical power change. The solid line 200 indicates a characteristic in a case where the gain control of the SOA 23 is performed by the above-mentioned gain control circuit 27 at the rapid optical power change. The dotted line 300 indicates a characteristic in a case where the gain control according to JP 08-331062 A is performed at the rapid optical power change. Further, the lower portion of FIG. 5 illustrates temporal aspects of the LOS issuance and cancellation (level change) corresponding to the respective characteristics 100, 200, and 300.

It can be seen from the upper portion of FIG. 5 that in a case where the gain control of the SOA 23 is not performed at the rapid optical power change, the input optical power to the ROSA 25 is the fastest to reach the LOS cancellation level. Therefore, as denoted by the solid line 400 in the lower portion of FIG. 5, in a case where the gain control of the SOA 23 is not performed at the rapid optical power change, the timing to cancel the LOS alarm (transition from the H level to the L level) is the fastest compared to the other cases.

Meanwhile, it can be seen from the upper portion of FIG. 5 that in a case where the aforementioned gain control according to JP 08-331062 A is performed at the rapid optical power change, the input optical power to the ROSA 25 is the latest to reach the LOS cancellation level. Therefore, as denoted by the solid line 600 in the lower portion of FIG. 5, in a case where the gain control by JP 08-331062 A is performed at the rapid optical power change, the timing to cancel the LOS alarm (transition from the H level to the L level) is the latest compared to the other cases.

In contrast, in a case where the gain control of the SOA 23 by the above-mentioned gain control circuit 27 is performed, the input optical power to the ROSA 25 reaches the LOS cancellation level faster than the case where the gain control according to JP 08-331062 A is performed, as illustrated in the upper portion of FIG. 5 (the solid line 200). However, the input optical power to the ROSA 25 reaches the LOS cancellation level slower than the case of no gain control of the SOA 23. Therefore, as denoted by the solid line 500 in the lower portion of FIG. 5, the timing for the LOS cancellation is delayed compared to the case of no gain control (see the solid line 400). The delay time is illustrated as Δt in the lower portion of FIG. 5. In the second embodiment, the delay time Δt is suppressed or removed.

FIG. 6 is a block diagram illustrating an exemplary configuration of an optical receiver according to the second embodiment. The optical receiver 20 illustrated in FIG. 6 is different from the configuration illustrated in FIG. 1 in that a LOS alarm (ALM) control circuit 29 including the LOS cancellation delay prevention circuit 291 is additionally provided. The LOS alarm control circuit 29 may serve as an example a controller or a control block together with the gain control circuit 27 and the MPU 28.

The LOS alarm control circuit 29 is an example of an alarm signal control circuit, and controls the timing for issuing and cancelling the LOS alarm by using the LOS cancellation delay prevention circuit 291 in order to minimize the above-mentioned delay time Δt.

For example, the LOS cancellation delay prevention circuit 291 outputs the LOS signal of the optical receiver 20 based on the output signal (the CDR LOS signal) of the CDR (with LOS function) unit 26 and the optical signal level information from the gain control circuit 27 (for example, the gain subtraction circuit 271). The “optical signal level information” is an example of a detection result by the monitor PD 24.

For example, the LOS cancellation delay prevention circuit 291 generates the LOS signal output from the optical receiver 20 using either the CDR LOS signal or the optical signal level information having the faster LOS issuance timing or the faster LOS cancellation timing. At the rapid optical power change, the LOS signal output generated based on the optical signal level information from the gain subtraction circuit 271 has the faster LOS cancellation timing than that of the CDR LOS signal. Therefore, the LOS cancellation delay prevention circuit 291 outputs the former as the LOS signal of the optical receiver 20. The LOS issuance level and the LOS cancellation level are set in the MPU 28 in advance. Thus, it is possible to prevent the LOS cancellation timing from being delayed.

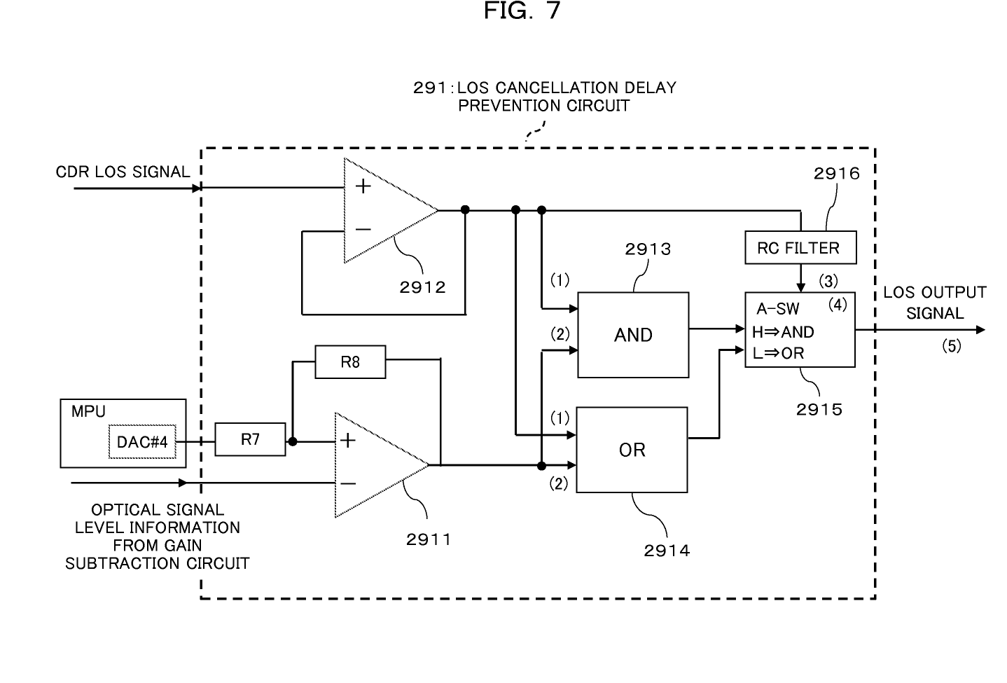

FIG. 7 illustrates an exemplary configuration of the LOS cancellation delay prevention circuit 291. The LOS cancellation delay prevention circuit 291 illustrated in FIG. 7 includes, for example, a comparator 2911, an operational amplifier 2912, an AND circuit 2913, an OR circuit 2914, an analog switch (A-SW) 2915, and an RC filter 2916. The AND circuit 2913 and the OR circuit 2914 may be realized by a logic IC, for example.

The comparator 2911 is, for example, a comparator having a hysteresis characteristic, and the positive (+) input terminal thereof is connected to a resistor R7 and a feedback resistor R8. A degree of hysteresis is determined by a ratio of resistance values of the resistor R7 and the feedback resistor R8. A threshold value is given from the MPU 28 (for example, DAC #4) to the positive input terminal of the comparator 2911. Meanwhile, the optical signal level information is input from the gain subtraction circuit 271 to the negative (−) input terminal of the comparator 2911.

When the threshold value is set to the same level as that of the CDR LOS signal, the LOS signal output of the optical receiver 20 can be set to the same LOS issuance or cancellation level as that of the CDR LOS signal. For example, when the optical signal level information from the gain subtraction circuit 271 is equal to or lower than the threshold value, the comparator 2911 outputs a signal (for example, an H level) indicating a LOS issuance state. On the contrary, when the optical signal level information from the gain subtraction circuit 271 exceeds the threshold value, a signal (for example, an L level) indicating a LOS cancellation state is output. The output of the comparator 2911 is input to each of the AND circuit 2913 and the OR circuit 2914.

The operational amplifier 2912 buffers the CDR LOS signal input from the CDR (with LOS function) unit 26 and then outputs the buffered signal to each of the AND circuit 2913, the OR circuit 2914, and the RC filter 2916.

The AND circuit 2913 outputs a signal obtained by a logical product of the outputs of the comparator 2911 and the operational amplifier 2912 to the analog switch 2915.

The OR circuit 2914 outputs a signal obtained by a logical sum of the outputs of the comparator 2911 and the operational amplifier 2912 to the analog switch 2915.

The RC filter 2916 is a filter using a resistor (R) and a capacitor (C), and filters the output of the operational amplifier 2912 to generate a control signal (hereinafter, also referred to as an “A-SW switching signal”) to switch the analog switch 2915.

The analog switch 2915 selects one of the outputs of the AND circuit 2913 and the OR circuit 2914 according to the A-SW switching signal, and outputs the selected signal as the LOS output signal of the optical receiver 20. For example, when the A-SW switching signal is at the H level, the analog switch 2915 selects the output of the AND circuit 2913 as the LOS output signal. On the contrary, when the A-SW switching signal is at the L level, the analog switch 2915 selects the output of the OR circuit 2914 as the LOS output signal.

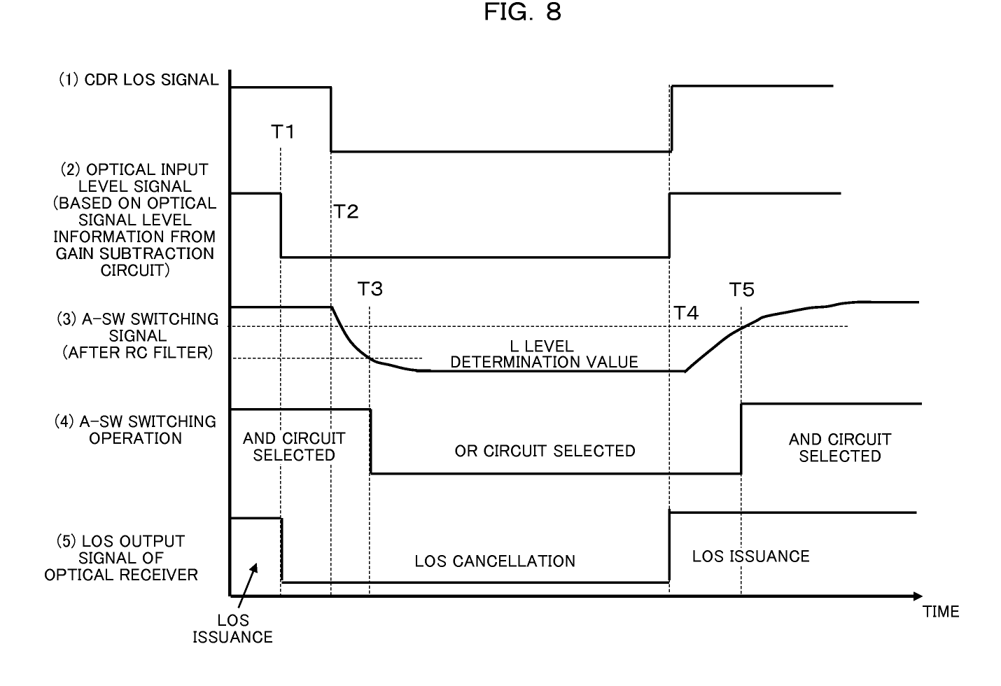

Hereinafter, the operation the LOS cancellation delay prevention circuit 291 with above-described configuration will be described with reference to a timing chart illustrated in FIG. 8. The signals or the operations illustrated in (1) to (5) of FIG. 8 correspond to the signals or the operations illustrated in (1) to (5) of FIG. 7, respectively.

Firstly, a case where a state transitions from a LOS alarm issuance state to a LOS alarm cancellation state at the rapid optical power change in which the input power to the optical receiver 20 is rapidly increased from the no-signal state will be described. Since the CDR LOS signal is in the LOS issuance state (at the H level) in the no-signal state, the A-SW switching signal rises to the H level. Therefore, the analog switch 2915 selects the output of the AND circuit 2913.

Herein, as illustrated in (1) of FIG. 8, a timing at which the CDR LOS signal transitions from the LOS issuance state (the H level) to the LOS cancellation state (the L level) is T2. Meanwhile, as illustrated in (2) of FIG. 8, a timing at which the output (which is based on the optical signal level information from the gain subtraction circuit 271) of the comparator 2911 transitions from the LOS issuance state (the H level) to the LOS cancellation state (the L level) is T1 earlier than timing T2.

Therefore, the output of the AND circuit 2913 becomes the L level at the timing T1 earlier than timing T2 at which the CDR LOS signal transitions to the L level. As illustrated in (3) and (4) of FIG. 8, since the analog switch 2915 selects the output of the AND circuit 2913, the LOS output signal (5) of the optical receiver 20 falls in the L level at timing T1 earlier than timing T2 at which the CDR LOS signal transitions to the L level. In other words, the optical receiver 20 becomes in the LOS cancellation state. Therefore, the delay time Δt of the LOS cancellation described in FIG. 5 can be minimized.

As illustrated in (3) of FIG. 8, even when the CDR LOS signal transitions to the L level, the A-SW switching signal gradually goes down to the L level taking a time corresponding to a time constant determined by the RC values of the RC filter 2916. Therefore, as illustrated in (4) of FIG. 8, even when the CDR LOS signal transitions to the L level, the analog switch 2915 selects the output of the AND circuit 2913 for a while (for example, until timing T3).

Then, at timing T3 in (3) and (4) of FIG. 8, when it is determined that the A-SW switching signal goes down to a certain level or less and the A-SW switching signal is considered to be fallen in the L level, the analog switch 2915 selects the output (the L level) of the OR circuit 2914. Therefore, the LOS output signal (5) of the optical receiver 20 is at the L level.

Next, the operation in a case where the LOS alarm is issued from the LOS cancellation state (in other words, the LOS output signal of the optical receiver 20 is at the L level) will be described.

In the LOS cancellation state, when the optical signal level input to the optical receiver 20 is decreased and reaches the LOS issuance level, both of the CDR LOS signal and the optical input level signal are switched from the L level to the H level as illustrated in (1) and (2) of FIG. 8. At this time, since the A-SW switching signal is at the L level, the analog switch 2915 selects the output of the OR circuit 2914.

The output of the OR circuit 2914 rises to the H level at a timing of either the CDR LOS signal or the optical input level signal illustrated in (1) and (2) of FIG. 8, whichever comes earlier to be switched from the L level to the H level. In the example of FIG. 8, the optical input level signal (2) is switched from the L level to the H level at timing T4 earlier than that of the CDR LOS signal (1).

Therefore, the output of the OR circuit 2914 rises to the H level at timing T4. Thereby, the LOS output signal (5) of the optical receiver 20, which is output from the analog switch 2915, is switched from the L level (the LOS cancellation state) to the H level (the LOS issuance state) at timing T4.

Thereafter, when it is determined at timing T5 that the CDR LOS signal (1) rises to the H level and thus the A-SW switching signal (3) rises to the H level, for example, the analog switch 2915 selects the output of the AND circuit 2913. At this time, since both of the CDR LOS signal (1) and the optical input level signal (2) are at the H level, the output of the AND circuit 2913 is also at the H level. Therefore, the LOS output signal (5) of the optical receiver 20, which is output from the analog switch 2915, remains at the H level (or remains the LOS issuance state).

### Third Embodiment

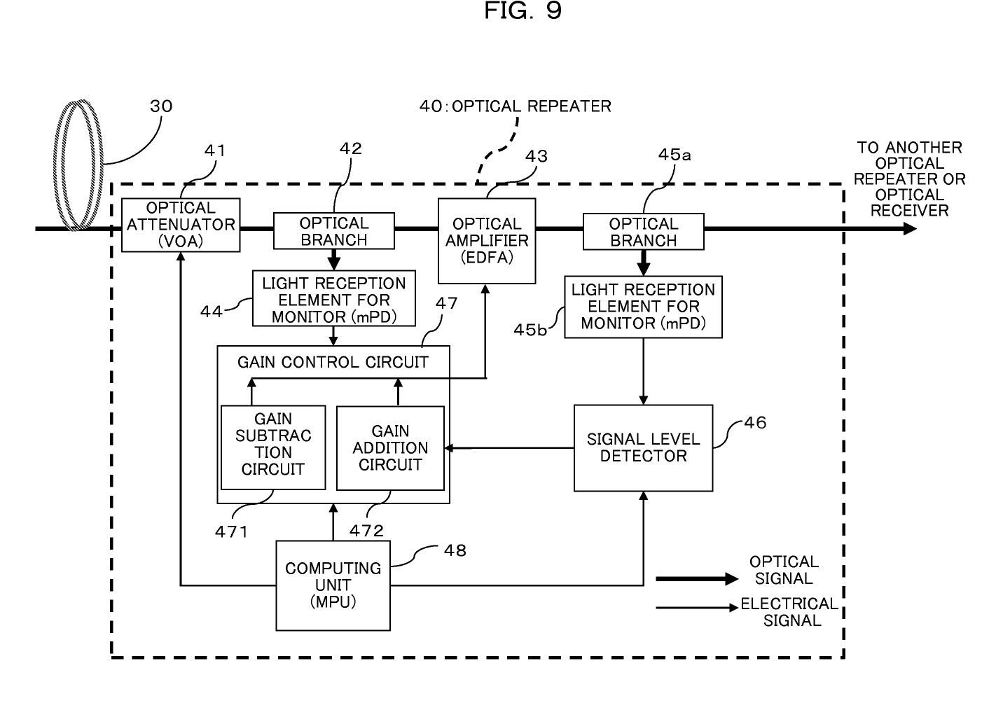

The gain control (gain subtraction and gain addition) by the gain control circuit 27 described in the first embodiment may be applied to an optical repeater, for example. An example is illustrated in FIG. 9. FIG. 9 is a block diagram illustrating an exemplary configuration of an optical repeater 40 according to a third embodiment.

The optical repeater 40 illustrated in FIG. 9 amplifies an optical signal received from an optical transmission line 30 and transmits the amplified signal to another optical repeater or optical receiver, for example. The optical signal to be transmitted through the optical transmission line 30 may be an optical signal with one wavelength, or may be a WDM optical signal in which optical signals with multiple wavelengths are multiplexed.

The optical repeater 40 illustrated in FIG. 9 includes, for example, a variable optical attenuator (VOA) 41, an optical branch section 42, an optical amplifier 43, light reception elements 44 and 45b for monitor, an optical branch section 45a, a signal level detector 46, a gain control circuit 47, and a computing unit 48.

The VOA 41 is controlled its attenuation amount (loss) by the computing unit 48 to adjust the output optical power of the optical signal received from the optical transmission line 30 to the optical branch 42.

The optical branch 42 branches the output light of the VOA 41, and outputs one of the branched light as a monitor light the monitor light reception element 44, and outputs the other of the branched light to the optical amplifier 43. An optical coupler is applicable to the optical branch 42.

The optical amplifier 43 amplifies the light input from the optical branch 42 and outputs the amplified light to the optical branch 45a. The optical amplifier 43 is, for example, an optical fiber amplifier (EDFA) in which erbium (which is an example of a rare earth element) is doped, and an amplification gain thereof is controlled by the gain control circuit 47. The gain of the EDFA 43 is set to an initial setting value at an optical interruption state. The initial setting value is, for example, a value which satisfies a minimum reception level of the monitor light reception element 45b.

The monitor light reception element 44 outputs an electrical signal according to a light reception power of the monitor light branched at the optical branch 42 to the gain control circuit 47. A photo diode (PD) is applicable to the light reception element 44. The “mPD” illustrated in FIG. 9 an abbreviation of a monitor PD.

The optical branch 45a outputs a part of the optical signal amplified by the EDFA 43 as the monitor light to the monitor light reception element 45b, and outputs the optical signal to another optical repeater or optical receiver.

The monitor light reception element 45b (or mPD) outputs an electrical signal (for example, a current value) according to a light reception power of the monitor light branched at the optical branch 45a to the signal level detector 46.

The signal level detector 46 detects an output signal level of a monitor PD 45b, and gives the detection result to a gain addition circuit 472 of the gain control circuit 47. The detected level of the signal level detector 46 is set by an MPU 48, for example.

The MPU 48 performs control on the attenuation amount (or the VOA loss) of the VOA 21, setting on the signal level detector 46 such as a detection level, and setting on the gain control circuit 47. For example, the setting on the gain control circuit 47 may include a setting of a target value and an upper limit of the gain of the EDFA 43.

The gain control circuit 47 performs the same gain control as that of the gain control circuit 27 of the first embodiment on the EDFA 43. For example, the gain control circuit 47 performs the processes P11 to P20 described above with reference to FIG. 2. Therefore, the optical response of the EDFA 43 is accelerated, and thus a time taken for establishing the signal communication at the rapid optical power change can be shortened.

Therefore, the gain control circuit 47 includes a gain subtraction circuit 471 and the gain addition circuit 472 corresponding to the gain subtraction circuit 271 and the gain addition circuit 272 of the first embodiment, respectively.

Similarly to the first embodiment, when the input optical power reaches the first level PL1, the gain subtraction circuit 471 performs a subtract operation on the gain of the EDFA 43 to be decreased according to the input optical power based on current information from a monitor PD 44. Therefore, the first level PL1 may be referred to as a “gain subtraction start level”. The “gain subtraction start level” is set by the MPU 48, for example.

When the input optical power reaches the second level PL2 at the rapid optical power change, the gain addition circuit 472 performs an add operation on the gain of the EDFA 43 to be increased. Therefore, the second level PL2 may be referred to as a “gain addition start level”. Further, when the input optical power reaches, for example, the third level PL3 near the target value and the monitor value of the current value (which is an example of the gain control signal given to the EDFA 43) reaches the target value, the gain addition circuit 472 limits and stops the increase of the gain of the EDFA 43. At this time, the gain addition circuit 472 may decrease the gain of the EDFA 43. The gain addition start level, a gain addition amount, and the target value of the gain addition circuit 472 may be set by the MPU 48, for example.

By using the gain subtraction circuit 471 and the gain addition circuit 472, it is possible to prevent the monitor PD 45b from being input an optical power exceeding the maximum reception level due to an optical transient response at the rapid optical power change. Therefore, it is possible to prevent the monitor PD 45b from being damaged. Also, a time taken until the optical repeater 40 becomes operable can be shortened by stabilizing the gain of the EDFA 43. Therefore, it is possible to suppress a delay in a time taken for establishing the signal communication and the response time of the reception power monitor.

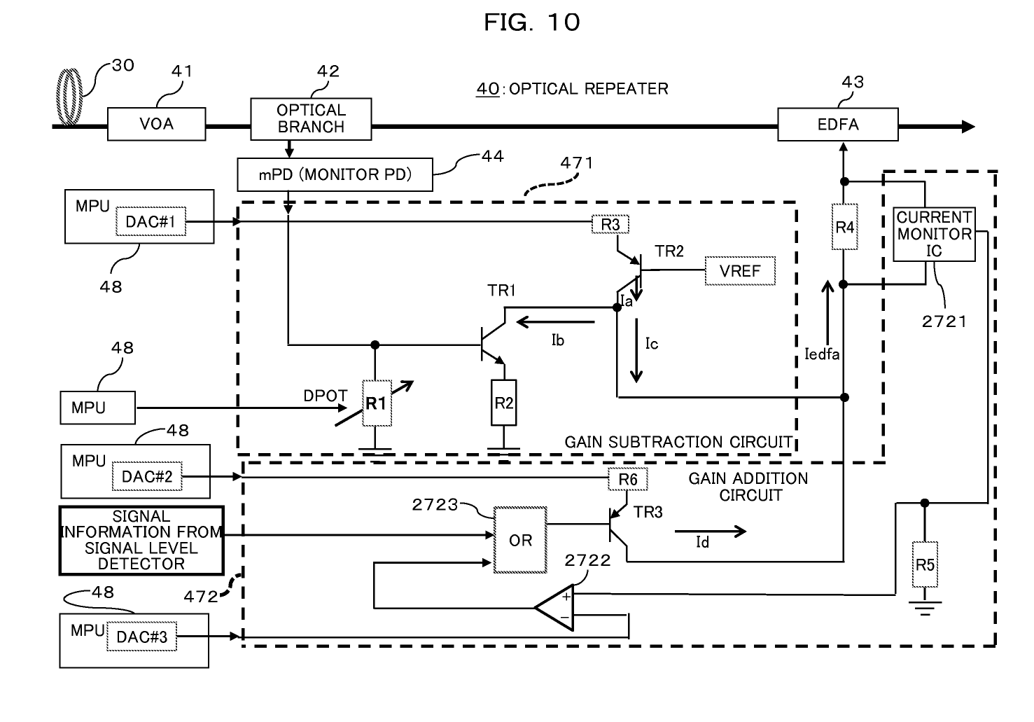

FIG. 10 illustrates an exemplary configuration of the optical repeater 40, focusing on the gain subtraction circuit 471 and the gain addition circuit 472. As can be seen from the comparison between FIG. 10 and FIG. 4 of the first embodiment, the gain subtraction circuit 471 may have the same configuration as that of the gain subtraction circuit 271 illustrated in FIG. 4.

Meanwhile, the gain addition circuit 472 may have the same configuration as that of the gain addition circuit 272 illustrated in FIG. 4 except that the output of the signal level detector 46 is input to the OR circuit 2723 instead of the CDR LOS signal.

Hereinafter, the operations of the gain subtraction circuit 471 and the gain addition circuit 472 will be described.

### Operation Example of Gain Subtraction Circuit 471

Firstly, the gain of the EDFA 43 is determined by DAC #1 of the MPU 48. The determination is performed in the no-signal state. In the no-signal state, the transistor TR1 is in the OFF state, and therefore, the gain of the EDFA 43 is determined by the transistor TR2. Subsequently, an attenuation start level is determined by using the MPU 48 and the digital variable resistor R1. In this case, the determination is made in consideration of the output (or transmission) level of the optical repeater 40.

When an optical signal is input to the optical repeater 40, a base voltage of the transistor TR1 is increased according to the output of the monitor PD 44, and the transistor TR1 is turned on at a certain level. The turning-on level of the transistor TR1 is determined by the digital variable resistor R1. When the transistor TR1 is turned on, the current Ib flows from the collector of the transistor TR2 to the collector of the transistor TR1.

When an input optical signal level (in other words, the output level of the monitor PD 44) to the optical repeater 40 is increased, the current Ib is also increased. Therefore, the current Ic expressed by Ic=Ia−Ib is decreased when the input optical signal level is increased. In this way, the gain subtraction circuit 471 operates to decrease the gain of the EDFA 43 at the rapid optical power change by controlling the current Ic.

### Operation Example of Gain Addition Circuit 472

Meanwhile, the gain addition circuit 472 operates as follows.

Firstly, the gain addition amount of the EDFA 43 is determined by DAC #2 of the MPU 48. When the transistor TR3 becomes the ON state, a current Id is output from the collector of the transistor TR3. The current Id is added to the current Ic which is output from the collector of the transistor TR2 of the gain subtraction circuit 471. Therefore, since the current Iedfa given to the EDFA 43 is increased, the gain of the EDFA 43 is increased and the optical transient response of the EDFA 43 is accelerated.

The turning ON/OFF timing of the transistor TR3 is determined based on detection level information from the signal level detector 46 and upper limit information of the current Iedfa. For example, a signal to be input to one input terminal of the OR circuit 2723 falls in the L level at the detection timing (transition from the H level to the L level) of the signal level detector 46. Meanwhile, the output of the comparator 2722 which is input to the other input terminal of the OR circuit 2723 is at the L level until the current value of the current Iedfa detected by the current monitor IC 2721 reaches the target value which is set from the MPU 48 (DAC #3).

Therefore, the output of the OR circuit 2723 becomes the L level, and the transistor TR3 becomes the ON state. Thereby, the current Id from the collector of the transistor TR3 is output to increase the current Iedfa. Accordingly, the gain of the EDFA 43 is increased, and therefore, the optical transient response of the EDFA 43 is accelerated.

Thereafter, when the current value of the current Iedfa detected by the current monitor IC 2721 exceeds the target value set from the MPU 48 (DAC #3), the output of the comparator 2722 rises to the H level. Therefore, the output of the OR circuit 2723 becomes the H level, and the transistor TR3 becomes the OFF state. The target value of the current Iedfa is adjusted by the MPU 48 (DAC #3). Thereby, the optical rising time is delayed, and thus it is possible to prevent the monitor PD 45b from being input the optical surge by way of the addition of the gain of the EDFA 43.

As described above, the gain addition circuit 472 operates such that the gain of the EDFA 43 is increased at the rapid optical power change by controlling the turning ON and OFF of the transistor TR3.

The following three methods are exemplified as a method of detecting a signal level (or PD current information) by the signal level detector 46, which level (or information) defines an operation start timing of the gain addition circuit 472 as described above.

(1) A method of detecting a peak level of the output current value of the monitor PD 45b

(2) A method of detecting a bottom level of the output current value of the monitor PD 45b

(3) A method of detecting an average level of the output current value of the monitor PD 45b

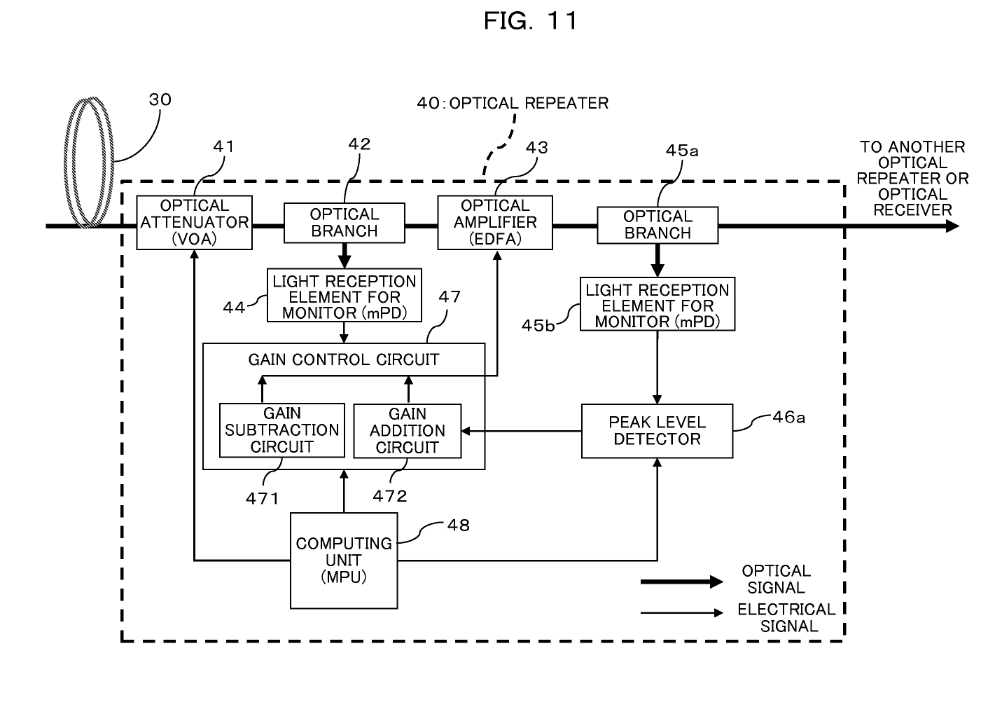

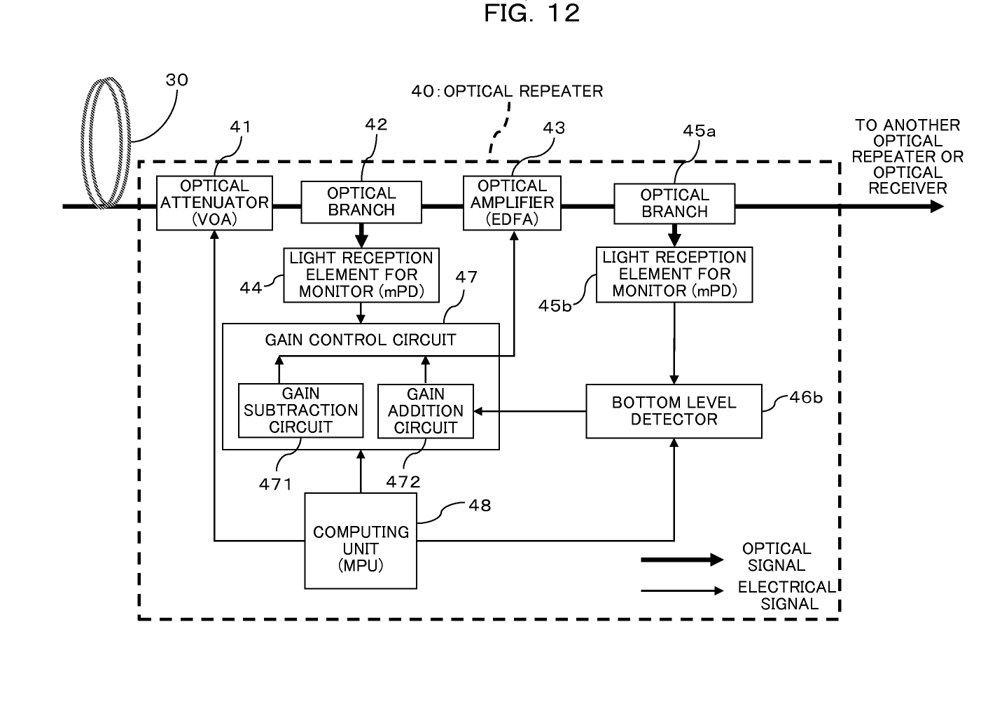

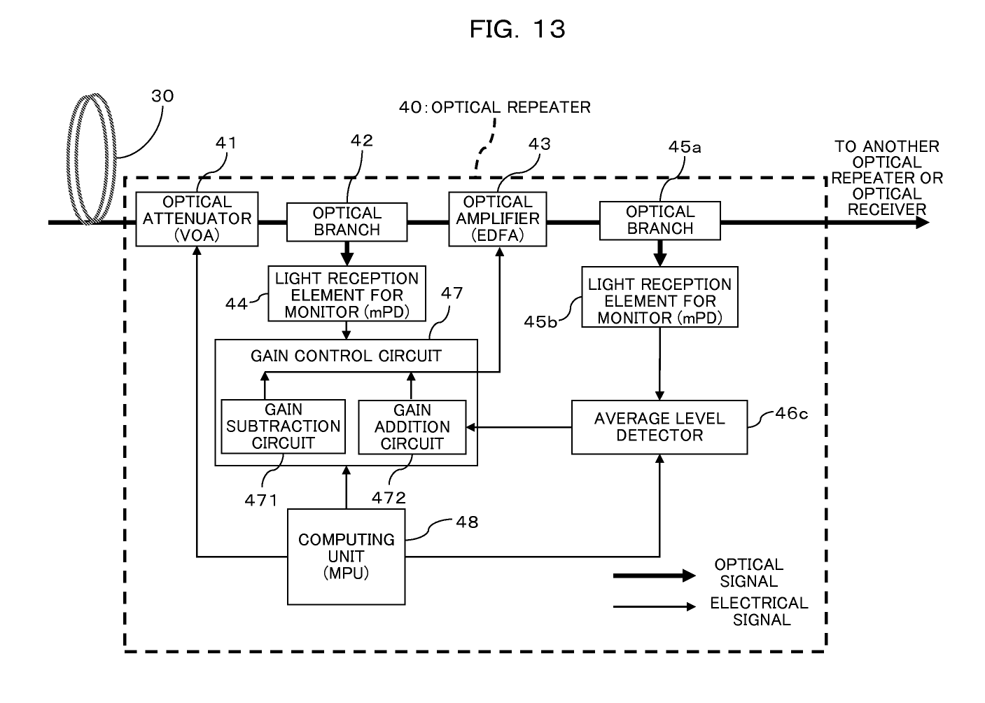

In the case of (1), as illustrated in FIG. 11, the optical repeater 40 may include a peak level detector 46a as an example of the signal level detector 46. In the case of (2), as illustrated in FIG. 12, the optical repeater 40 may include a bottom level detector 46b as an example of the signal level detector 46. In the case of (3), as illustrated in FIG. 13, the optical repeater 40 may include an average level detector 46c as an example of the signal level detector 46.

### Modified Example of First Embodiment

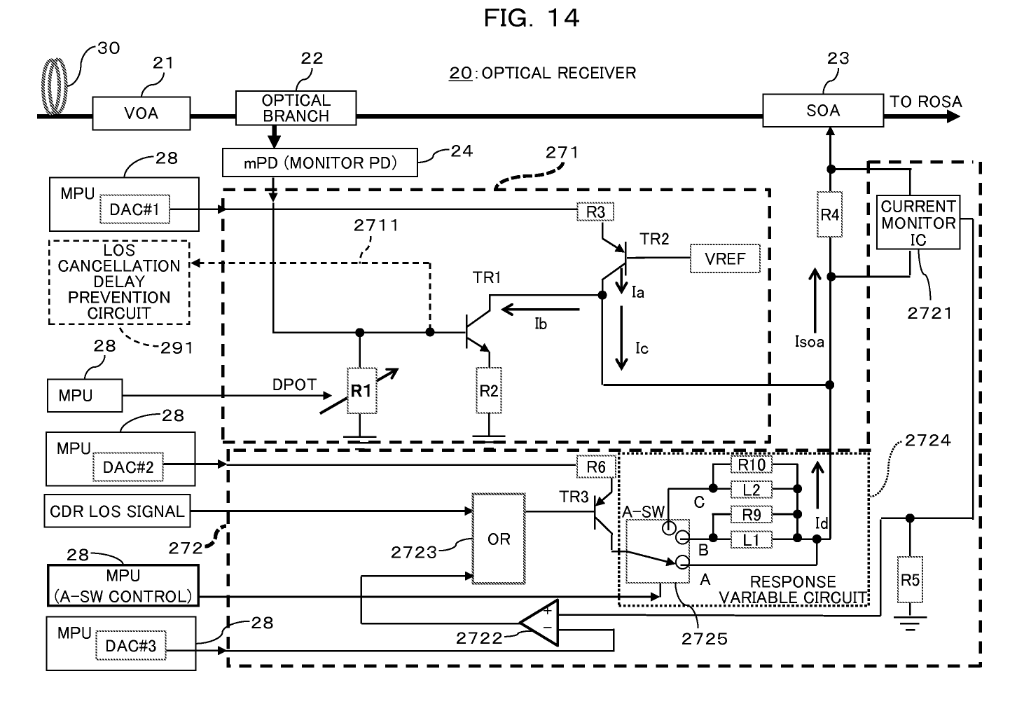

FIG. 14 is a block diagram illustrating an exemplary configuration of the optical receiver according to a modified example of the first embodiment (for example, FIG. 4). The optical receiver 20 illustrated in FIG. 14 is different from the configuration illustrated in FIG. 4 in that a response variable circuit 2724 in the gain addition circuit 272 is provided in a signal line from the collector of the transistor TR3 to the SOA 23.

The response variable circuit 2724 adjusts, for example, an increasing rate (hereinafter, may be referred to as an “accelerating rate”) of the current Id which increases the current Isoa applied to the SOA 23 by the control of the MPU 28. Therefore, it is possible to adjust the accelerating rate to increase the gain of the SOA 23.

Therefore, the response variable circuit 2724 may include an analog switch (A-SW) 2725, a resistor R9, a resistor R10, a coil L1, and a coil L2, for example.

The analog switch 2725 has one input terminal and three output terminals A, B, and C, for example, and the input terminal is switched according to the control signal from the MPU 28 and connected to any one of the three output terminals A, B, and C.

The input terminal of the analog switch 2725 is connected to the collector of the transistor TR3. The output terminal A of the analog switch 2725 is connected to a signal line leading to the resistor R4 through a first route (hereinafter, may be referred to as “Route A”) where the resistor R9, the resistor R10, the coil L1, and the coil L2 are not provided. The output terminal B is connected to a signal line leading to the resistor R4 through a second route (hereinafter, may be referred to as “Route B”) where the coil L1 is provided. The output terminal C is connected to a signal line leading to the resistor R4 through a third route (hereinafter, may be referred to as “Route C”) where the coil L2 is provided.

Therefore, in response to the switching of the output terminals A, B, and C of the analog switch 2725, a route of the current Id flowing from the collector of the transistor TR3 to the SOA 23 through the resistor R4 can be switched to any one of the three Routes A to C.

In a case where Route A is selected, since the gain addition circuit 272 corresponds to the same circuit configuration as that of the first embodiment (FIG. 4), the accelerating rate of the current Id does not different from the first embodiment. On the contrary, in a case where Route B or C is selected, since the current Id flows through the coil L1 or L2, the accelerating rate becomes lower than that in the case of Route A.

The accelerating rate becomes lowered as an inductance of the coil is increased. For descriptive purpose, when inductances of the coils L1 and L2 are represented by L1 and L2, respectively, and when L1<L2, the accelerating rate becomes L1>L2. In this way, the accelerating rate is varied according to the inductances of the coils L1 and L2. The inductances of the coils L1 and L2 are, for example, set in advance according to an accelerating rate to be requested. The resistor R9 is connected to the coil L1 in parallel, and the resistor R10 is connected to the coil L2 in parallel. These parallel-connected resistors R9 and R10 make it possible to suppress a resonance (Q value) caused by the coils L1 and L2.

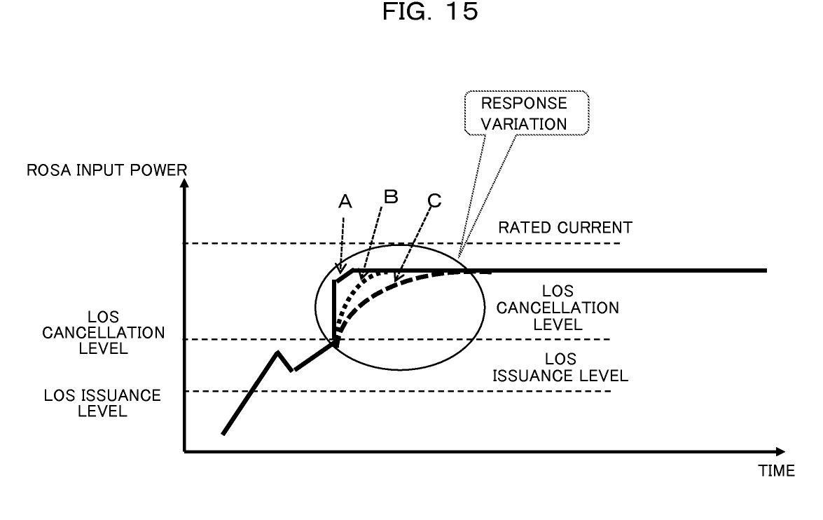

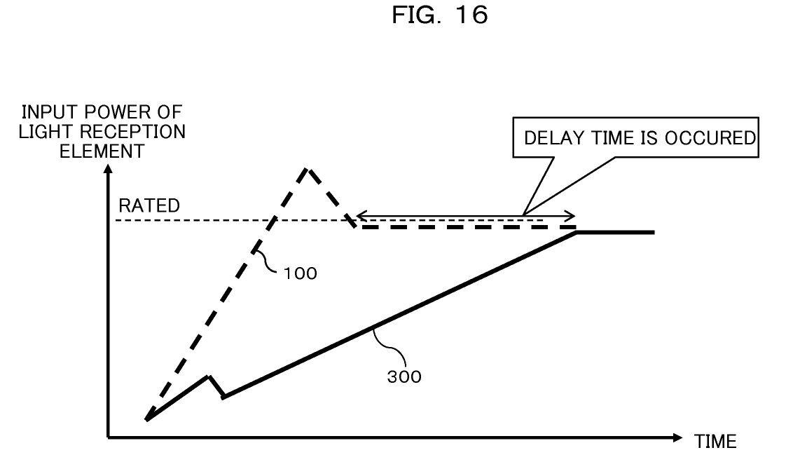

The analog switch 2725 is possible to vary the increasing rate of the gain of the SOA 23 by selecting any one of three Routes A to C having different accelerating rates in accordance with the control signal from the MPU 28. Therefore, as illustrated in FIG. 15, it is possible to vary the accelerating rate of the input optical power to the ROSA 25 as denoted with arrows A to C, for example. The arrows A to C indicate the response characteristics when Routes A to C are selected, respectively.

As described above, according to the modified example of the first embodiment, since the response variable circuit 2724 makes it possible to change the optical response characteristic of the optical receiver 20 at the rapid optical power change, it is possible to flexibly satisfy a required characteristic. The response variable circuit 2724 may be applied to the above-mentioned second embodiment, and may be applied to the above-mentioned third embodiment.

According to the above-mentioned technology, even when the rapid optical power change is occurred, it is possible to achieve both of the prevention of the damage of the light reception element and the acceleration of the optical response speed.

All examples and conditional language provided herein are intended for pedagogical purposes to aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiment(s) of the present invention have been described in detail, it should be understood that the various changes, substitutions, and alterations could be made hereto without departing from the spirit and scope of the invention.

What is claimed is:

1. An optical communication apparatus comprising:
an optical amplifier configured to amplify a received optical signal;
a light reception element configured to receive the optical signal amplified by the optical amplifier; and
a controller configured to
decrease a gain of the optical amplifier according to an optical signal power input to the optical amplifier in response to a detection of a recovery of the optical signal input to the optical amplifier from an interruption of the optical signal, and
increase the gain of the optical amplifier so that an input optical power to the light reception element approaches a target value after the decreasing of the gain.

2. The optical communication apparatus according to claim 1, further comprising:
a detector configured to detect the input optical signal power,
wherein the controller includes
a gain subtraction circuit configured to decrease the gain of the optical amplifier according to the input optical signal power when the input optical signal power detected by the detector reaches a first level, and
a gain addition circuit configured to increase the gain of the optical amplifier when the input optical signal power reaches a second level larger than the first level.

3. The optical communication apparatus according to claim 2, wherein
the gain addition circuit stops increasing the gain when the gain approaches a gain at which the input optical signal power corresponds to a power at a third level larger than the second level.

4. The optical communication apparatus according to claim 2, wherein
the first level is set to a level larger than a lower limit of a reception range of the light reception element and smaller than an alarm cancellation level at which an issuance of an alarm signal indicating a loss of an optical signal is cancelled, and
the second level is set to the alarm cancellation level.

5. The optical communication apparatus according to claim 3, wherein
the first level is set to a level larger than a lower limit of a reception range of the light reception element and smaller than an alarm cancellation level at which an issuance of an alarm signal indicating a loss of an optical signal is cancelled, and
the second level is set to the alarm cancellation level.

6. The optical communication apparatus according to claim 4, wherein
the third level is set to a level larger than the alarm cancellation level and smaller than the target value.

7. The optical communication apparatus according to claim 5, wherein
the third level is set to a level larger than the alarm cancellation level and smaller than the target value.

8. The optical communication apparatus according to claim 1, further comprising
an alarm signal functioning unit configured to issue or cancel an alarm signal indicating a loss of an optical signal according to a level of the optical signal received by the light reception element,
wherein the controller includes
an alarm signal control circuit configured to control timing of an issuance or a cancellation of the alarm signal based on a detection result of the detector and a signal indicating the issuance or cancellation of the alarm signal.

9. The optical communication apparatus according to claim 1, wherein
the optical communication apparatus is an optical receiver configured to include a semiconductor amplifier as the optical amplifier.

10. The optical communication apparatus according to claim 2, wherein
the optical communication apparatus is an optical receiver configured to include a semiconductor amplifier as the optical amplifier.

11. The optical communication apparatus according to claim 1, wherein
the optical communication apparatus is an optical repeater configured to include a rare earth element doped optical fiber amplifier as the optical amplifier.

12. The optical communication apparatus according to claim 2, wherein
the optical communication apparatus is an optical repeater configured to include a rare earth element doped optical fiber amplifier as the optical amplifier.

13. The optical communication apparatus according to claim 1, wherein
the controller includes
a response variable circuit configured to vary an increasing rate of the gain.

14. A control method of an optical communication apparatus that includes an optical amplifier configured to amplify a received optical signal and a light reception element configured to receive the optical signal amplified by the optical amplifier, the method comprising:
decreasing a gain of the optical amplifier according to an optical signal power input to the optical amplifier in response to a detection of a recovery of the optical signal input to the optical amplifier from an interruption of the optical signal; and
increasing the gain so that an input optical power to the light reception element approaches a target value after the decreasing of the gain.
